(19) United States
(12) Patent Application Publication
(10) Pub. No.: US 2025/0051905 A1
(43) Pub. Date: Feb. 13, 2025

(54) DEPOSITION MODULE AND DISPLAY DEVICE MANUFACTURING APPARATUS INCLUDING THE SAME

(71) Applicant: Samsung Display Co., Ltd., Yongin-Si (KR)

(72) Inventors: Hwapyeong Jeong, Yongin-si (KR); Mingyu Seo, Yongin-si (KR); Sangmin Jung, Yongin-si (KR); Ganyoung Park, Yongin-si (KR); Jonggun Yun, Yongin-si (KR); Kyoungwoon Lee, Yongin-si (KR)

(21) Appl. No.: 18/597,957

(22) Filed: Mar. 7, 2024

(30) Foreign Application Priority Data
Aug. 9, 2023 (KR) 10-2023-0104344

(51) Int. Cl. C23C 14/24; C23C 14/04; H10K 71/16

(52) U.S. Cl. CPC C23C 14/243; C23C 14/042; H10K 71/166

(57) ABSTRACT

A display device manufacturing apparatus includes a mask assembly, and a deposition module configured to supply a deposition material toward the mask assembly. The deposition module includes a deposition frame, a spraying portion, a heater, and a close contact portion. The deposition frame has an internal space. The spraying portion includes a crucible portion and a nozzle portion. The heater heats the nozzle portion and is configured to be switchable between a first state and a second state with a higher heating value than the first state. The close contact portion brings the crucible portion and the nozzle portion into close contact with each other, and the close contact portion includes a pressing surface spaced apart from the spraying portion in the first state and configured to press on the spraying portion in the second state.

### CROSS-REFERENCE TO RELATED APPLICATION

This application is based on and claims priority under 35 U.S.C. § 119 to Korean Patent Application No. 10-2023-0104344, filed on Aug. 9, 2023, in the Korean Intellectual Property Office, the disclosure of which is incorporated by reference herein in its entirety.

### BACKGROUND

### 1. Field

One or more embodiments relate to an apparatus, and more particularly, to a deposition module and a display device manufacturing apparatus.

### 2. Description of the Related Art

Recently, electronic devices have been widely used. Electronic devices are used in various ways, such as mobile electronic devices and fixed electronic devices. Such electronic devices include display devices to provide visual information, such as images or videos, to users in order to support various functions.

A display device is configured to display data visually and is manufactured by depositing various layers such as organic layers and metal layers. Deposition materials may be deposited so as to form a plurality of layers of a display device. That is, a deposition material is sprayed from a deposition source and deposited on a substrate through a mask assembly.

The background art is technical information possessed by the inventors for the derivation of the disclosure or obtained during the derivation of the disclosure, and is not necessarily known technology disclosed to the general public prior to the filing of the disclosure.

### SUMMARY

According to embodiments, a deposition material does not leak through a gap between a crucible portion and a nozzle portion during a deposition process, and the crucible portion is easily separated from the nozzle portion when the deposition process is completed.

However, this is only an example, and the technical problems to be solved by the disclosure are not limited thereto.

Additional aspects will be set forth in part in the description which follows and, in part, will be apparent from the description, or may be learned by practice of the presented embodiments of the disclosure.

According to one or more embodiments, a display device manufacturing apparatus includes a mask assembly, and a deposition source including a deposition module configured to supply a deposition material toward the mask assembly. The deposition module includes a deposition frame, a spraying portion, a heater, and a close contact portion. The deposition frame has an internal space. The spraying portion is accommodated in the internal space and includes a crucible portion configured to provide a storage space for storing the deposition material, and a nozzle portion connected to the crucible portion and configured to spray the deposition material stored in the storage space. The heater is accommodated in the internal space so as to heat the nozzle portion and is configured to be switchable between a first state and a second state, the second state having a heating value higher than a heating value of the first state. The close contact portion is accommodated in the internal space so as to bring the crucible portion and the nozzle portion into close contact with each other, and the close contact portion includes a pressing surface spaced apart from the spraying portion in the first state and configured to press on the spraying portion in the second state.

In the present embodiment, at least one of the crucible portion or the nozzle portion may have a thermal expansion coefficient that is higher than a thermal expansion coefficient of the close contact portion.

In the present embodiment, the crucible portion may include a carbon material and the nozzle portion may include a metal material.

In the present embodiment, the close contact portion may be detachable from the spraying portion in the first state.

In the present embodiment, the crucible portion may include a first crucible portion configured to store the deposition material and having a longitudinal direction in a first direction toward the nozzle portion, and a second crucible portion protruding from the first crucible portion in a second direction crossing the first direction. The nozzle portion may include a first nozzle portion in contact with the crucible portion, and a second nozzle portion configured to discharge the deposition material and protruding from the first nozzle portion in the first direction. The close contact portion may be configured to press on the second crucible portion and the first nozzle portion in the second state.

In the present embodiment, a first accommodation groove may be disposed in a lower surface of the second crucible portion, and a first end portion of the close contact portion may be accommodated in the first accommodation groove.

In the present embodiment, the close contact portion may be further configured to press on an upper surface of the first nozzle portion in the second state.

In the present embodiment, a second accommodation groove may be disposed in the upper surface of the first nozzle portion, and a second end portion of the close contact portion may be accommodated in the second accommodation groove.

In the present embodiment, a second accommodation groove may be disposed in a side surface of the first nozzle portion, and a second end portion of the close contact portion may be disposed in the second accommodation groove and configured to press on the nozzle portion in the second state.

In the present embodiment, the display device manufacturing apparatus may further include a support portion configured to support the spraying portion from the deposition frame, wherein the close contact portion may be fixed to the support portion, and the pressing surface may face one surface of the nozzle portion.

In the present embodiment, the close contact portion may include a close contact frame fixed to the support portion, and a plurality of pressing portions protruding from the close contact frame toward one surface of the nozzle portion. The plurality of pressing portions include pressing surfaces including the pressing surface, and the pressing surfaces of the plurality of pressing portions may be spaced apart from each other.

In the present embodiment, a separation opening configured to separate at least two of the plurality of pressing portions from each other may be arranged in the close contact frame.

In the present embodiment, in the second state, the at least two of the plurality of pressing portions may have different heights.

In the present embodiment, the separation opening may include a first separation opening having a longitudinal direction, and a second separation opening connected to an end portion of the first separation opening and having a circular planar shape.

In the present embodiment, the crucible portion and the close contact portion may include a same material.

According to one or more embodiments, a deposition module includes a deposition frame, a spraying portion, a heater, and a close contact portion. The deposition frame has an internal space. The spraying portion is accommodated in the internal space and includes a crucible portion having a storage space for storing a deposition material, and a nozzle portion connected to the crucible portion and configured to spray the deposition material stored in the storage space. The heater is accommodated in the internal space so as to heat the nozzle portion and is configured to be switchable between a first state and a second state, the second state having a heating value higher than a heating value of the first state. The close contact portion is accommodated in the internal space of the deposition frame so as to bring the crucible portion and the nozzle portion into close contact with each other. The close contact portion includes a pressing surface spaced apart from the spraying portion in the first state and configured to press on the spraying portion in the second state.

In the present embodiment, at least one of the crucible portion or the nozzle portion may have a thermal expansion coefficient that is higher than a thermal expansion coefficient of the close contact portion.

In the present embodiment, the crucible portion may include a carbon material and the nozzle portion may include a metal material.

In the present embodiment, the close contact portion may be detachable from the spraying portion in the first state.

In the present embodiment, the close contact portion may be provided in a form of a clamp.

### BRIEF DESCRIPTION OF THE DRAWINGS

The above and other aspects and features of certain embodiments of the disclosure will be more apparent from the following description taken in conjunction with the accompanying drawings.

FIG. 1 is a cross-sectional view illustrating a display device manufacturing apparatus according to an embodiment.

FIG. 2 is a schematic perspective view of a deposition source according to an embodiment.

FIG. 3 is a cross-sectional view of the deposition source of FIG. 2 taken along line I-I′ of FIG. 2, according to an embodiment.

FIG. 4 is a schematic cross-sectional view of a portion of a deposition module in a first state, according to an embodiment.

FIG. 5 is a schematic cross-sectional view of a portion of a deposition module in a second state, according to an embodiment.

FIG. 6 is a schematic cross-sectional view of a portion of a deposition module in a first state, according to an embodiment.

FIG. 7 is a schematic cross-sectional view of a portion of a deposition module in a second state, according to an embodiment.

FIG. 8 is a schematic cross-sectional view of a portion of a deposition module in a first state, according to an embodiment.

FIG. 9 is a schematic cross-sectional view of a portion of a deposition module in a second state, according to an embodiment.

FIG. 10 is a schematic cross-sectional view of a portion of a deposition module in a first state, according to an embodiment.

FIG. 11 is a schematic plan view of a close contact portion according to an embodiment.

FIG. 12 is a schematic cross-sectional view of a portion of a deposition module in a second state, according to an embodiment.

FIG. 13 is a schematic side view of a portion of a deposition module in a second state, according to an embodiment.

FIG. 14 is a plan view schematically illustrating a display device manufactured by using a display device manufacturing apparatus, according to an embodiment.

FIG. 15 is a cross-sectional view schematically illustrating a display device manufactured by using a display device manufacturing apparatus, according to an embodiment.

FIG. 16 is an equivalent circuit diagram of a pixel of a display panel, according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the present description allows for various changes and numerous embodiments, certain embodiments will be illustrated in the drawings and described in detail in the written description. Effects and features of the disclosure, and methods of achieving them will be clarified with reference to embodiments described below in detail with reference to the drawings. However, the disclosure is not limited to the following embodiments and may be embodied in various forms.

Hereinafter, embodiments will be described in detail with reference to the accompanying drawings. When describing embodiments with reference to the accompanying drawings, the same or corresponding elements are denoted by the same reference numerals.

It will be understood that although the terms “first,” “second,” etc. may be used herein to describe various elements, these elements should not be limited by these terms. These terms are only used to distinguish one element from another.

The singular forms as used herein are intended to include the plural forms as well unless the context clearly indicates otherwise.

It will be further understood that the terms “include” and/or “comprise” used herein specify the presence of stated features or elements, but do not preclude the presence or addition of one or more other features or elements.

It will be further understood that, when a layer, region, or element is referred to as being “on” another layer, region, or element, it may be directly or indirectly on the other layer, region, or element. That is, for example, intervening layers, regions, or elements may be present.

Also, sizes of elements in the drawings may be exaggerated or reduced for convenience of explanation. For example, because sizes and thicknesses of elements in the drawings are arbitrarily illustrated for convenience of explanation, the disclosure is not limited thereto.

The x-axis, the y-axis, and the z-axis are not limited to three axes of the rectangular coordinate system and may be interpreted in a broader sense. For example, the x-axis, the y-axis, and the z-axis may be perpendicular to one another or may represent different directions that are not perpendicular to one another.

When a certain embodiment may be implemented differently, a specific process order may be performed differently from the described order. For example, two consecutively described processes may be performed substantially at the same time or performed in an order opposite to the described order.

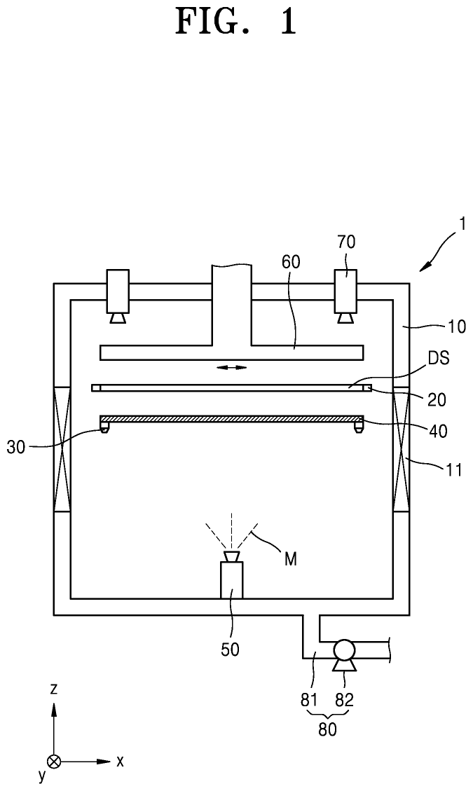

FIG. 1 is a cross-sectional view illustrating a display device manufacturing apparatus 1 according to an embodiment.

The display device manufacturing apparatus 1 may include a chamber 10, a first support portion 20, a second support portion 30, a mask assembly 40, a deposition source 50, a magnetic force portion 60, a vision portion 70, and a pressure controller 80.

A space may be formed inside the chamber 10. A display substrate DS and the mask assembly 40 may be accommodated in the chamber 10. A portion of the chamber 10 may be formed to be open, and a gate valve 11 may be installed in the open portion of the chamber 10. In this case, the open portion of the chamber 10 may be opened or closed according to the operation of the gate valve 11.

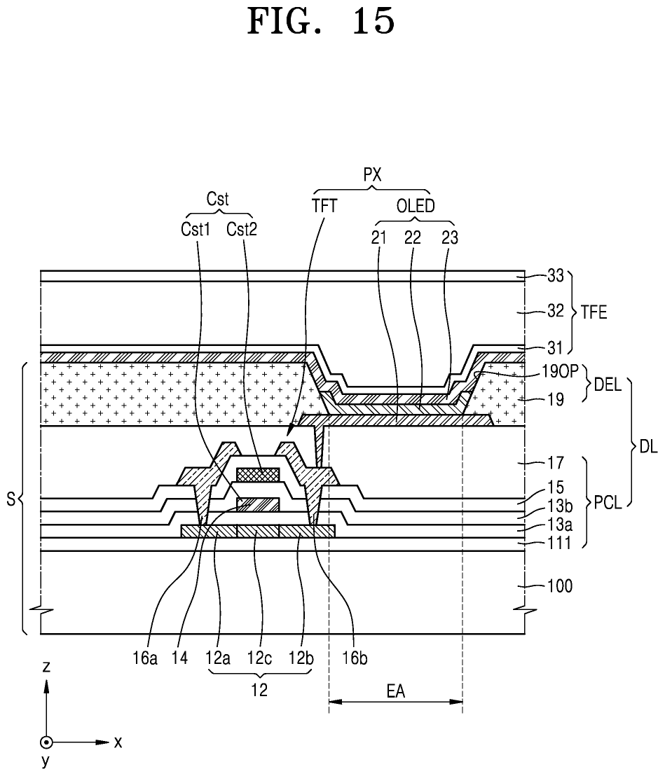

The display substrate DS may refer to a display substrate DS in a process of manufacturing a display device in which at least one of an organic layer, an inorganic layer, or a metal layer is deposited on a substrate 100, e.g., see FIG. 15, to be described below. Alternatively, the display substrate DS may be a substrate 100 on which any of the organic layer, the inorganic layer, and the metal layer has not yet been deposited.

The first support portion 20 may support the display substrate DS. The first support portion 20 may be in the form of a plate fixed inside the chamber 10. In an embodiment, the first support portion 20 may be in the form of a shuttle on which the display substrate DS is seated and capable of linear movement within the chamber 10. In an embodiment, the first support portion 20 may include an electrostatic chuck or an adhesive chuck that is fixed to the chamber 10 or is disposed in the chamber 10 so as to be movable within the chamber 10.

The second support portion 30 may support the mask assembly 40. The second support portion 30 may be arranged in the chamber 10. The second support portion 30 may finely adjust the position of the mask assembly 40. The second support portion 30 may include a separate driver or aligner (alignment unit) so as to enable the mask assembly 40 to move in different directions.

In an embodiment, the second support portion 30 may be in the form of a shuttle. In this case, the mask assembly 40 may be seated on the second support portion 30, and the second support portion 30 may transfer the mask assembly 40. For example, the second support portion 30 may move outside the chamber 10 and enter the chamber 10 from the outside of the chamber 10 after the mask assembly 40 is seated thereon.

At this time, the first support portion 20 and the second support portion 30 may be integrally formed as a single body. In this case, the first support portion 20 and the second support portion 30 may include a movable shuttle. At this time, the first support portion 20 and the second support portion 30 may include a structure for fixing the mask assembly 40 to the display substrate DS with the display substrate DS seated on the mask assembly 40, and may simultaneously linearly move the display substrate DS and the mask assembly 40.

However, for convenience of explanation, the following description is given focusing on a case where the first support portion 20 and the second support portion 30 are formed to be distinct from each other and arranged in different positions and a case where the first support portion 20 and the second support portion 30 are arranged in the chamber 10.

The mask assembly 40 may be arranged in the chamber 10 so as to face the display substrate DS. A deposition material M may pass through the mask assembly 40 and be deposited on the display substrate DS.

The deposition source 50 may be arranged so as to face the mask assembly 40 and may supply the deposition material M so that the deposition material M passes through a deposition area of the mask assembly 40 and is deposited on the display substrate DS. At this time, the deposition source 50 may vaporize or sublimate the deposition material M by applying heat to the deposition material M. The deposition source 50 may be fixedly arranged in the chamber 10 or may be arranged in the chamber 10 so as to enable linear movement in one direction.

The magnetic force portion 60 may be arranged in the chamber 10 so as to face the display substrate DS and/or the mask assembly 40. At this time, the magnetic force portion 60 may apply magnetic force to the mask assembly 40 so as to force the mask assembly 40 toward the display substrate DS. In particular, the magnetic force portion 60 may prevent the mask assembly 40 from sagging and may allow the mask assembly 40 to be adjacent to the display substrate DS. Additionally, the magnetic force portion 60 may maintain a uniform gap between the mask assembly 40 and the display substrate DS.

The vision portion 70 may be arranged in the chamber 10 and may capture images of the positions of the display substrate DS and the mask assembly 40. At this time, the vision portion 70 may include a camera configured to capture images of the display substrate DS and the mask assembly 40. Based on the images captured by the vision portion 70, the positions of the display substrate DS and the mask assembly 40 may be determined and the deformation of the mask assembly 40 may be identified. In addition, based on the images, the position of the display substrate DS on the first support portion 20 may be finely adjusted, or the position of the mask assembly 40 on the second support portion 30 may be finely adjusted. However, the following description is given in detail focusing on a case where the positions of the display substrate DS and the mask assembly 40 are aligned by finely adjusting the position of the mask assembly 40 on the second support portion 30.

The pressure controller 80 may be connected to the chamber 10 and configured to control the internal pressure of the chamber 10. For example, the pressure controller 80 may adjust the internal pressure of the chamber 10 so as to be equal to or similar to atmospheric pressure. In addition, the pressure controller 80 may adjust the internal pressure of the chamber 10 so as to be equal to or similar to a vacuum state.

The pressure controller 80 may include a connection pipe 81 connected to the chamber 10 and a pump 82 installed in the connection pipe 81. At this time, depending on the operation of the pump 82, external air may be introduced through the connection pipe 81, or gas inside the chamber 10 may be guided to the outside through the connection pipe 81.

On the other hand, in a method of manufacturing a display device (not shown) by using the display device manufacturing apparatus 1, the display substrate DS may be prepared in advance.

The pressure controller 80 may maintain the inside of the chamber 10 at a state equal to or similar to atmospheric pressure, and the gate valve 11 may operate to open the open portion of the chamber 10.

Thereafter, the display substrate DS may be loaded from the outside to the inside of the chamber 10. At this time, the display substrate DS may be loaded into the chamber 10 in various ways. For example, the display substrate DS may be inserted from the outside to the inside of the chamber 10 through a robot arm arranged outside the chamber 10. In an embodiment, in a case where the first support portion 20 is formed in the form of a shuttle, after the first support portion 20 is unloaded from the inside to the outside of the chamber 10, the display substrate DS may be seated on the first support portion 20 through a separate robot arm arranged outside the chamber 10, and the first support portion 20 may be loaded from the outside to the inside of the chamber 10.

The mask assembly 40 may be in a state of being arranged in the chamber 10, as described above. In an embodiment, the mask assembly 40 may be loaded from outside to the inside of the chamber 10 in the same or similar manner as the display substrate DS.

When the display substrate DS is loaded into the chamber 10, the display substrate DS may be seated on the first support portion 20. At this time, the vision portion 70 may capture the images of the positions of the display substrate DS and the mask assembly 40. The positions of the display substrate DS and the mask assembly 40 may be determined based on the images captured by the vision portion 70. At this time, the display device manufacturing apparatus 1 may include a separate controller (not shown) so as to determine the positions of the display substrate DS and the mask assembly 40.

Once the positions of the display substrate DS and the mask assembly 40 are determined, the second support portion 30 may finely adjust the position of the mask assembly 40.

Thereafter, the deposition source 50 may operate to supply the deposition material M to the mask assembly 40, and the deposition material M having passed through a plurality of pattern holes of the mask assembly 40 may be deposited on the display substrate DS. At this time, the deposition source 50 may move parallel to the display substrate DS and the mask assembly 40, or the display substrate DS and the mask assembly 40 may move parallel to the deposition source 50. That is, the deposition source 50 may move relative to the display substrate DS and the mask assembly 40. At this time, the pump 82 may suction in gas inside the chamber 10 and discharge the gas to the outside so as to maintain the internal pressure of the chamber 10 to be equal to or similar to a vacuum.

As described above, the deposition material M supplied from the deposition source 50 may pass through the mask assembly 40 and be deposited on the display substrate DS. Accordingly, at least one of a plurality of layers that are stacked in a display device to be described below, for example, an organic layer, an inorganic layer, and a metal layer, may be formed.

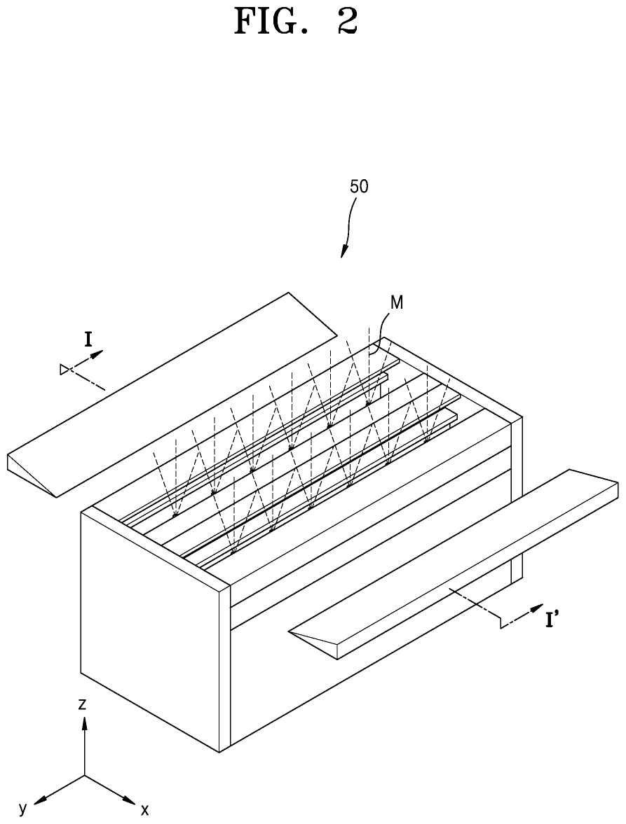

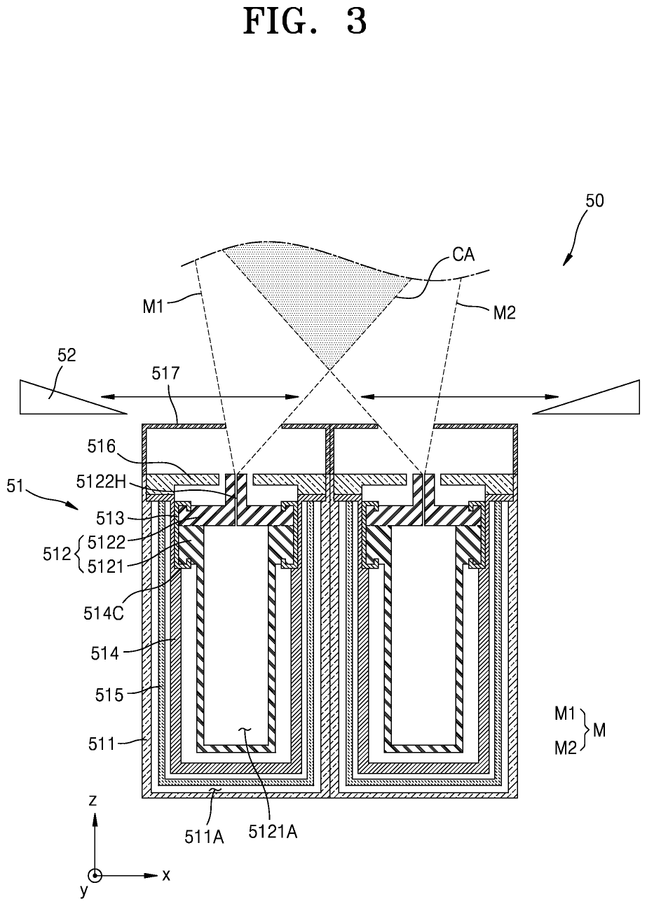

FIG. 2 is a schematic perspective view of the deposition source 50 according to an embodiment. FIG. 3 is a cross-sectional view of the deposition source 50 of FIG. 2 taken along line I-I′ of FIG. 2, according to an embodiment.

Referring to FIGS. 1 to 3, the deposition source 50 according to an embodiment may include a deposition module 51 and a shutter 52.

The deposition module 51 may supply a deposition material M so that the deposition material M passes through the mask assembly 40 and is deposited on a display substrate DS. The deposition module 51 may include a deposition frame 511, a spraying portion 512, a close contact portion 513, a support portion 514, a heater 515, a reflector 516, and an angle limiter 517.

The deposition frame 511 may form the exterior of the deposition module 51 and may provide an internal space 511A. The deposition frame 511 may be formed with one side open so that the deposition material M is sprayed to the outside. The deposition frame 511 may include a cooler. In such a structure, the deposition frame 511 may cool heat generated in the internal space 511A. Accordingly, the deposition frame 511 may reduce a phenomenon in which heat generated in the internal space 511A leaks to the outside and affects other components including a mask frame and a substrate. Although FIGS. 2 and 3 illustrate that the deposition frame 511 has a hexahedral shape with one side open, this is only an example, and the shape of the deposition frame 511 is not limited thereto.

The spraying portion 512 may be accommodated in the internal space 511A of the deposition frame 511 and may spray the stored deposition material M. The spraying portion 512 may include a crucible portion 5121 and a nozzle portion 5122.

The crucible portion 5121 may provide a storage space 5121A in which the deposition material M is stored. The deposition material M may be stored in the storage space 5121A of the crucible portion 5121. The nozzle portion 5122 may be connected to the crucible portion 5121 and may spray the deposition material M stored in the storage space 5121A of the crucible portion 5121. A spray hole 5122H through which the deposition material M is sprayed may be arranged in the nozzle portion 5122. The storage space 5121A of the crucible portion 5121 and the spray hole 5122H of the nozzle portion 5122 may communicate with each other.

The close contact portion 513 may be accommodated in the internal space 511A of the deposition frame 511 so as to bring the crucible portion 5121 and the nozzle portion 5122 into close contact with each other. The close contact portion 513 may apply pressure to at least one of the crucible portion 5121 or the nozzle portion 5122 so as to bring the crucible portion 5121 and the nozzle portion 5122 into close contact with each other. Therefore, a phenomenon in which the deposition material M leaks between the crucible portion 5121 and the nozzle portion 5122 during the process in which the spraying portion 512 sprays the deposition material M may be reduced.

The support portion 514 may support the spraying portion 512 from the deposition frame 511. The support portion 514 may be accommodated in the internal space 511A of the deposition frame 511. One side of the support portion 514 may be fixed to the deposition frame 511 and may be supported from the deposition frame 511. The support portion 514 may support the close contact portion 513 so that the spraying portion 512 fixed to the close contact portion is supported. For example, when the spraying portion 512 and the close contact portion 513 are accommodated in the support portion 514, one side of the close contact portion 513 may be supported by hanging on a stepped portion 514C disposed on the support portion 514. However, this is only an example, and a method by which the support portion 514 supports the spraying portion 512 is not limited thereto.

The heater 515 may be accommodated in the internal space 511A of the deposition frame 511 so as to heat the nozzle portion 5122. The heater 515 may be arranged to surround the spraying portion 512, the close contact portion 513, and the support portion 514. The heater 515 may be between the support portion 514 and the deposition frame 511. For example, as illustrated in FIG. 3, the heater 515 has a ‘C’-shaped cross-section and the spraying portion 512 may be accommodated in the heater 515. For example, the heater 515 may be supported from the deposition frame 511 by being fixed to the support portion 514. However, this is only an example, and the arrangement and shape of the heater 515 are not limited thereto.

The heater 515 may be switchable between a first state and a second state, the second state having a heating value higher than a heating value of the first state. The heater 515 may not heat the nozzle portion 5122 in the first state and may heat the nozzle portion 5122 in the second state. That is, in the first state, the spraying portion 512 may not spray the deposition material M, and in the second state, the spraying portion 512 may spray the deposition material M.

In the second state, the deposition material M stored in the crucible portion 5121 may be heated by the heater 515. The heater 515 may heat the side surface of the spraying portion 512 (e.g., the surface of the spraying portion 512 facing the x-axis direction) and the lower surface of the spraying portion 512 (e.g., the surface of the spraying portion 512 facing the −z-axis direction). As the heater 515 heats the deposition material M, the deposition material M stored in the crucible portion 5121 may be vaporized. Accordingly, the deposition material M vaporized by the heater 515 may be sprayed through the nozzle portion 5122. Additionally, in the second state, as the heater 515 heats the nozzle portion 5122, heat may be transferred to the deposition material M passing through the spray hole 5122H of the nozzle portion 5122. Therefore, a phenomenon in which temperature drops while the vaporized deposition material M passes through the nozzle portion 5122, and thus, the vaporized deposition material M solidifies and clogs the nozzle portion 5122 may be reduced.

For example, the heater 515 may include a heat-generating member that generates heat. The heat-generating member may directly generate heat. For example, a heating wire that generates heat may be disposed on the surface of the heater 515 facing the nozzle portion 5122. However, this is only an example, and a method by which the heater 515 heat the nozzle portion 5122 is not limited thereto.

The reflector 516 may block heat generated in the internal space 511A of the deposition frame 511 from being transferred to the mask assembly 40. The reflector 516 may be between the heater 515 and the mask assembly 40. In such a structure, the reflector 516 may prevent the mask assembly 40 or the display substrate DS from being damaged by heat transferred from the heater 515 to the mask assembly 40. In addition, a phenomenon in which heat generated in the internal space 511A of the deposition frame 511 is emitted to the outside may be reduced, and thus, the heat efficiency of the heater 515 may increase.

The reflector 516 may be connected to the deposition frame 511. When the deposition frame 511 includes a cooler, the deposition frame 511 may cool the reflector 516. In such the structure, the reflector 516 may efficiently block heat generated in the internal space 511A of the deposition frame 511 from being transferred to the mask assembly 40.

The angle limiter 517 may be connected to the deposition frame 511 and may limit the supply angle of the deposition material M supplied to the mask assembly 40. The angle limiter 517 may block a portion of the deposition material M sprayed through the nozzle portion 5122 from being supplied to the display substrate DS. That is, the angle limiter 517 may limit the supply angle of the deposition material M by passing only the deposition material M having a supply angle within a specified range.

A plurality of deposition modules 51 may be provided. For example, two deposition modules 51 may be provided. The two deposition modules 51 may be arranged side-by-side so as to supply the deposition material M toward the display substrate DS. One of the two deposition modules 51 may supply a first deposition material M1, and the other of the two deposition modules 51 may supply a second deposition material M2. The first deposition material M1 and the second deposition material M2 may be different materials. In the process of supplying the first deposition material M1 and the second deposition material M2, an overlap area CA where the first deposition material M1 and the second deposition material M2 overlap each other may be formed. In such a structure, a mixture of the first deposition material M1 and the second deposition material M2 may be deposited on the display substrate DS.

The first deposition material M1 and the second deposition material M2 may be different materials. For example, the first deposition material M1 may include a host component. In addition, the second deposition material M2 may include a dopant component. Consequently, a mixture of the host component and the dopant component may be deposited on the display substrate DS.

The shutter 52 may block the deposition material M supplied by the deposition module 51 from being deposited on the display substrate DS. The shutter 52 may prevent the deposition material M from reaching the display substrate DS by covering a portion of the deposition module 51.

As illustrated in FIGS. 2 and 3, the deposition material M may be deposited on the display substrate DS in a state in which the shutter 52 does not cover the deposition module 51. However, when the shutter 52 moves to cover a portion of the deposition module 51, the deposition material M may not be deposited on the display substrate DS. In such a structure, the thickness of the deposition material M deposited on the display substrate DS may be adjusted by adjusting the time for which the shutter 52 blocks the deposition material M.

The number of shutters 52 may correspond to the number of deposition modules 51. For example, when two deposition modules 51 are provided, two shutters 52 may be provided. When one shutter 52 blocks the first deposition material M1 from being supplied, the other shutter 52 may block the second deposition material M2 from being supplied. In addition, when one shutter 52 does not block the first deposition material M1 from being supplied, the other shutter 52 may not block the second deposition material M2 from being supplied. Accordingly, the first deposition material M1 and the second deposition material M2 may be simultaneously deposited on the display substrate DS or may be simultaneously blocked.

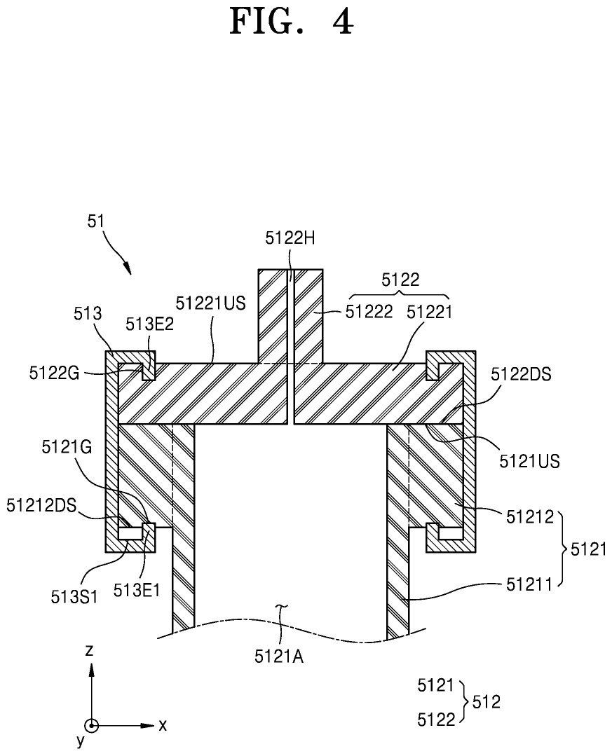

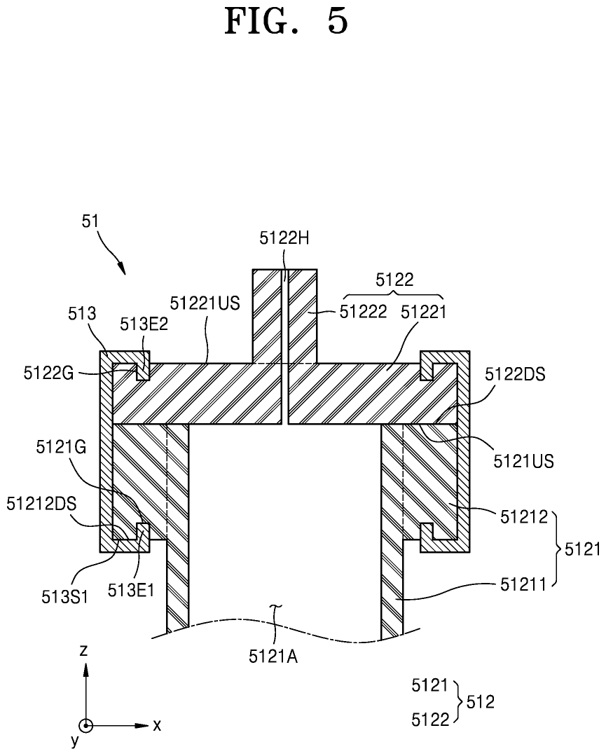

FIG. 4 is a schematic cross-sectional view of a portion of the deposition module 51 in the first state, according to an embodiment. FIG. 5 is a schematic cross-sectional view of a portion of the deposition module 51 in the second state, according to an embodiment.

In FIGS. 4 and 5, only the spraying portion 512 and the close contact portion 513 of the deposition module 51 are illustrated for convenience of explanation.

Referring to FIGS. 3 to 5, the close contact portion 513 may be provided in the form of a clamp.

The crucible portion 5121 may include a first crucible portion 51211 and a second crucible portion 51212. The first crucible portion 51211 may store the deposition material M and may have a longitudinal direction in a first direction (e.g., a z-axis direction) toward the nozzle portion 5122. That is, a storage space 5121A of the crucible portion 5121 may be arranged in the first crucible portion 51211.

The second crucible portion 51212 may protrude from the first crucible portion 51211 in a second direction (e.g., an x-axis direction). The second direction (e.g., the x-axis direction) may cross the first direction (e.g., the z-axis direction). An upper surface of the first crucible portion 51211 and an upper surface of the second crucible portion 51212 may form one plane. That is, the upper surface of the first crucible portion 51211 and the upper surface of the second crucible portion 51212 may form an upper surface 5121US of the crucible portion 5121.

The nozzle portion 5122 may include a first nozzle portion 51221 and a second nozzle portion 51222. The first nozzle portion 51221 may be in contact with the upper surface 5121US of the crucible portion 5121. The width of the first nozzle portion 51221 may be equal to the width of the crucible portion 5121. That is, a side surface of the first nozzle portion 51221 and a side surface of the second crucible portion 51212 may form one plane.

The second nozzle portion 51222 may discharge the deposition material M and may protrude from the first nozzle portion 51221 in the first direction (e.g., the z-axis direction). That is, the spray hole 5122H of the nozzle portion 5122 may pass through the first nozzle portion 51221 and the second nozzle portion 51222. As illustrated in FIG. 2, a plurality of second nozzle portions 51222 may be provided. The second nozzle portions 51222 may be arranged linearly. However, this is only an example, and the number and arrangement of the nozzle portions 5122 are not limited thereto.

The close contact portion 513 may be provided in the form of a clamp. In terms of the cross-section, the close contact portion 513 may include a C shape. The close contact portion 513 may be arranged on the side surfaces of the crucible portion 5121 and the nozzle portion 5122 so as to press the crucible portion 5121 and the nozzle portion 5122. The crucible portion 5121 and the nozzle portion 5122 may be partially accommodated in the close contact portion 513. A plurality of close contact portions may be provided. For example, two close contact portions 513 may be provided. The two close contact portions 513 may press on the crucible portion 5121 and the nozzle portion 5122 on both sides of the spraying portions 512.

A first accommodation groove 5121G may be arranged in a lower surface 51212DS of the second crucible portion 51212. A first end portion 513E1 of the close contact portion 513 may be accommodated in the first accommodation groove 5121G. In addition, a second accommodation groove 5122G may be arranged in an upper surface 51221US of the first nozzle portion 51221. A second end portion 513E2 of the close contact portion 513 may be accommodated in the second accommodation groove 5122G. In such a structure, a phenomenon in which the close contact portion 513 is unintentionally released from the crucible portion 5121 and the nozzle portion 5122 may be prevented.

The nozzle portion 5122 may include a metal material having a high heat transfer coefficient. Therefore, heat emitted from the heater may be easily transferred to the spray hole 5122H. Consequently, a phenomenon in which the deposition material M solidifies and clogs the spray hole 5122H may be reduced. For example, the nozzle portion 5122 may include a molybdenum-lanthanum (Mo—La) alloy. However, this is only an example, and the material of the nozzle portion 5122 is not limited thereto.

The crucible portion 5121 may include a material that is different from a material of the nozzle portion 5122. The crucible portion 5121 may include a material having a heat transfer coefficient that is lower than a heat transfer coefficient of the nozzle portion 5122. For example, the crucible portion 5121 may include a carbon material. Accordingly, a phenomenon in which the deposition material M solidifies and sticks between the crucible portion 5121 and the nozzle portion 5122, and thus, the crucible portion 5121 and the nozzle portion 5122 are attached to each other, may be reduced. Due to this, no separate mechanical or chemical treatment is required so as to separate the crucible portion 5121 from the nozzle portion 5122, which simplifies the manufacturing process and improves the durability of the deposition module. For example, the crucible portion 5121 may include a carbon composite (CC). However, this is only an example, and the crucible portion 5121 may include tungsten (W) or tantalum (Ta).

At least one of the crucible portion 5121 or the nozzle portion 5122 may have a thermal expansion coefficient that is higher than a thermal expansion coefficient of the close contact portion 513. For example, the crucible portion 5121 and the close contact portion 513 may include the same material. For example, the close contact portion 513 and the crucible portion 5121 may each include a CC, and the nozzle portion 5122 may include a Mo—La alloy. That is, the close contact portion 513 may have a thermal expansion coefficient that is lower than a thermal expansion coefficient of the nozzle portion 5122.

For example, in the process of manufacturing the crucible portion 5121, the crucible portion 5121 may be stacked in the first direction (e.g., the z-axis direction) toward the nozzle portion 5122. In addition, in the process of manufacturing the close contact portion 513, the close contact portions 513 may be stacked in the second direction (e.g., the x-axis direction) crossing the first direction (e.g., the z-axis direction). Accordingly, the thermal expansion coefficient of the crucible portion 5121 in the first direction (e.g., the z-axis direction) may be higher than the thermal expansion coefficient of the close contact portion 513 in the first direction (e.g., the z-axis direction).

When the first state in FIG. 4 is switched to the second state in FIG. 5, each of the heated crucible portion 5121, the heated nozzle portion 5122, and the heated close contact portion 513 may thermally expand. At this time, the close contact portion 513 may include a pressing surface 513S1 that is spaced apart from the spraying portion 512 in the first state and presses the spraying portion 512 in the second state.

As illustrated in FIG. 4, in the first state, the pressing surface 513S1 may be spaced apart from the spraying portion 512. For example, the pressing surface 513S1 may be spaced apart from the lower surface 51212DS of the second crucible portion 51212. Accordingly, in the first state, the close contact portion 513 may be detachable from the spraying portion 512. In the first state, the close contact portion 513 is separated from the spraying portion 512, and the crucible portion 5121 is separated from the nozzle portion 5122. Thereafter, the deposition material M is replenished in the storage space 5121A, or the spraying portion 512 may be cleaned.

As illustrated in FIG. 5, in the second state, the pressing surface 513S1 may press the spraying portion 512. Because the degree of thermal expansion of the nozzle portion 5122 and the crucible portion 5121 in the first direction (e.g., the z-axis direction) is greater than the degree of thermal expansion of the close contact portion 513 in the first direction (e.g., the z-axis direction), the pressing surface 513S1 may come into contact with the lower surface 51212DS of the second crucible portion 51212. Therefore, in the second state, the close contact portion 513 may press the second crucible portion 51212 and the first nozzle portion 51221 so that the nozzle portion 5122 and the crucible portion 5121 come into close contact with each other. In an embodiment, close contact means that at least two structures directly contact and press firmly against one another. That is, the upper surface 5121US of the crucible portion 5121 and the lower surface 5122DS of the nozzle portion 5122 may come into close contact with each other. Accordingly, leakage of the deposition material M between the nozzle portion 5122 and the crucible portion 5121 may be reduced.

As the pressing surface 513S1 is spaced apart from the spraying portion 512 in the first state, a phenomenon in which excessive pressure is applied to the close contact portion 513 in the second state may be reduced. Therefore, damage to the close contact portion 513 due to thermal expansion of the spraying portion 512 may be reduced.

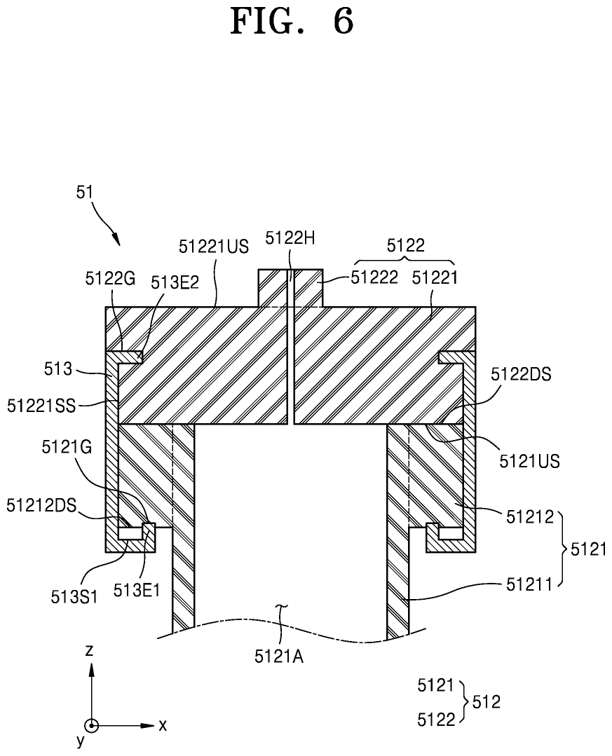

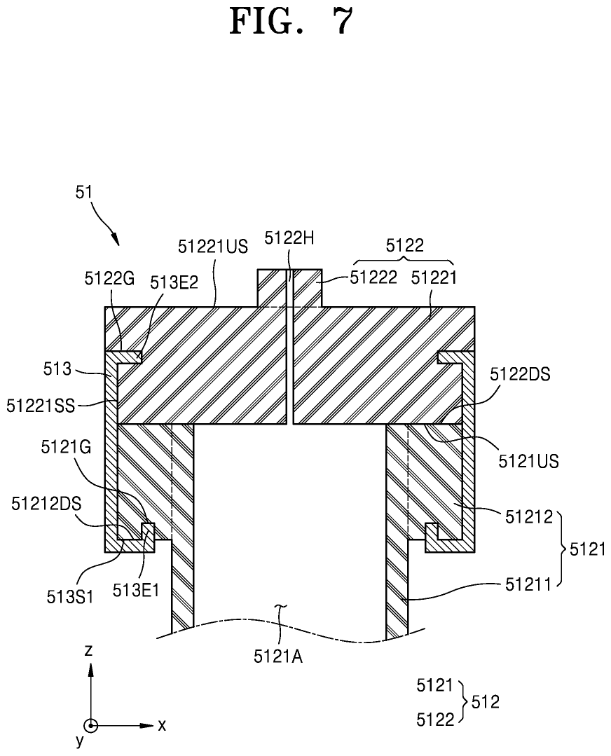

FIG. 6 is a schematic cross-sectional view of a portion of a deposition module 51 in a first state, according to an embodiment. FIG. 7 is a schematic cross-sectional view of a portion of the deposition module 51 in a second state, according to an embodiment.

In FIGS. 6 and 7, only a spraying portion 512 and a close contact portion 513 of the deposition module are illustrated for convenience of explanation.

In FIGS. 6 and 7, the same reference numerals as those in FIGS. 4 and 5 refer to the same members, and redundant descriptions thereof are omitted.

Referring to FIGS. 3, 6, and 7, the close contact portion 513 may be provided in the form of a clamp. In terms of the cross-section, the close contact portion 513 may include a C shape. The close contact portion 513 may be arranged on the side surfaces of the crucible portion 5121 and the nozzle portion 5122 so as to press the crucible portion 5121 and the nozzle portion 5122. The crucible portion 5121 and the nozzle portion 5122 may be partially accommodated in the close contact portion 513.

A first accommodation groove 5121G may be arranged in a lower surface 51212DS of the second crucible portion 51212. The first end portion 513E1 of the close contact portion 513 may be accommodated in the first accommodation groove 5121G. A second accommodation groove 5122G may be arranged in a side surface 51221SS of the first nozzle portion 51221, and a second end portion 513E2 of the close contact portion 513 may be arranged in the second accommodation groove 5122G. In addition, the second end portion 513E2 of the close contact portion 513 may press the nozzle portion 5122 in the second state.

In such a structure, a phenomenon in which the close contact portion 513 is unintentionally released from the crucible portion 5121 and the nozzle portion 5122 may be prevented. In addition, the area where the close contact portion 513 surrounds the nozzle portion 5122 may be reduced. Therefore, heat loss from the nozzle portion 5122 having high thermal conductivity to the close contact portion 513 having low thermal conductivity in the second state may be reduced. Due to this, a phenomenon in which the deposition material M solidifies and clogs the spray hole 5122H in the second state may be reduced.

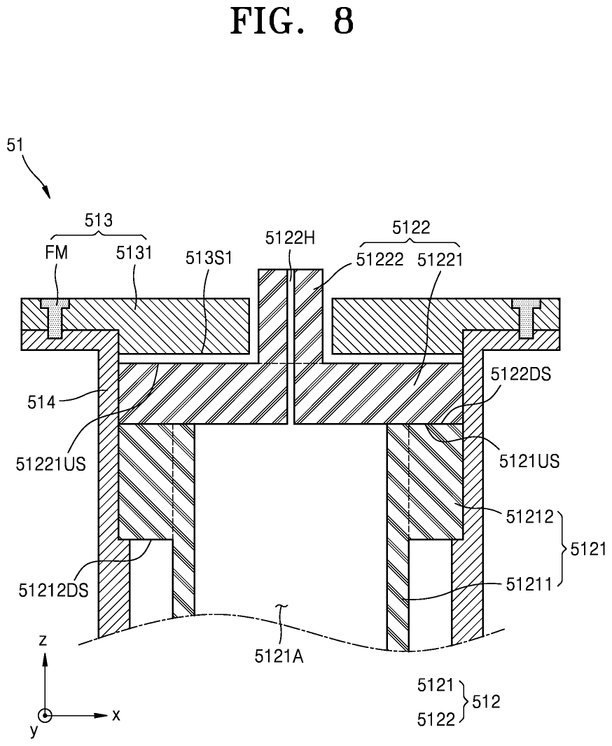

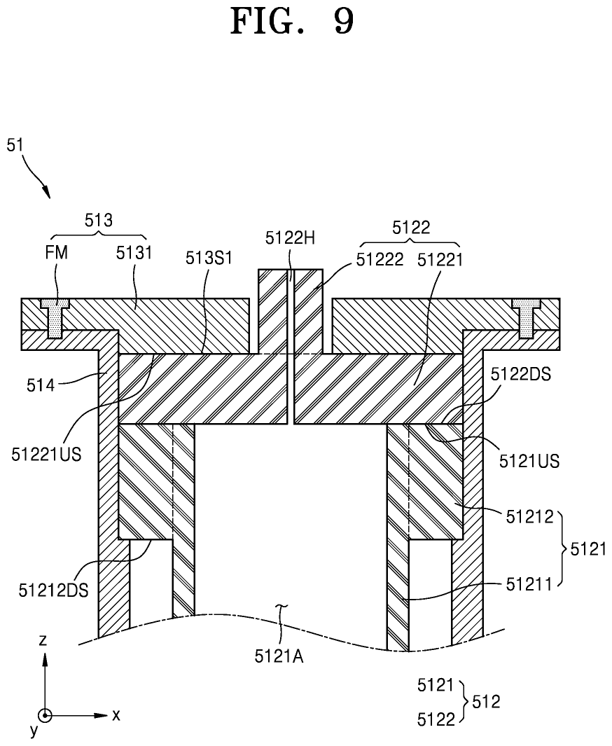

FIG. 8 is a schematic cross-sectional view of a portion of a deposition module 51 in a first state, according to an embodiment. FIG. 9 is a schematic cross-sectional view of a portion of the deposition module 51 in a second state, according to an embodiment.

In FIGS. 8 and 9, only a spraying portion 512, a close contact portion 513, and a support portion 514 of the deposition module 51 are illustrated for convenience of explanation.

In FIGS. 8 and 9, the same reference numerals as those in FIGS. 4 and 5 refer to the same members, and redundant descriptions thereof are omitted.

Referring to FIGS. 3, 8, and 9, the close contact portion 513 may be fixed to the support portion 514, and a pressing surface 513S1 may face one surface of a nozzle portion 5122. The close contact portion 513 may include a close contact frame 5131 and a fixing member FM.

The close contact frame 5131 may form the exterior of the close contact portion 513. The close contact frame 5131 may be fixed to the support portion 514. The pressing surface 513S1 may be disposed on the lower surface of the close contact frame 5131. The pressing surface 513S1 may face the upper surface 51221US of the first nozzle portion 51221.

The fixing member FM may fix the close contact frame 5131 to the support portion 514. The fixing member FM may have a screw shape. In such a structure, the close contact frame 5131 may be screwed to the support portion 514. However, this is only an example, and the method by which the fixing member FM fixes the close contact frame 5131 is not limited thereto.

In the first state, the close contact portion 513 and the spraying portion 512 may be spaced apart from each other, and in the second state, the close contact portion 513 may press the spraying portion 512. Accordingly, in the second state, the crucible portion 5121 and the nozzle portion 5122 may come into close contact with each other.

The thermal expansion coefficients of the support portion 514, the close contact portion 513, and the fixing member FM may be the same as each other. For example, the materials of the support portion 514, the close contact portion 513, and the fixing member FM may be the same as each other. Accordingly, the load applied to the fixing member FM may be reduced due to the thermal expansion of the support portion 514 and the close contact portion 513. Due to this, the external force applied to the fixing member FM in the second state may be reduced.

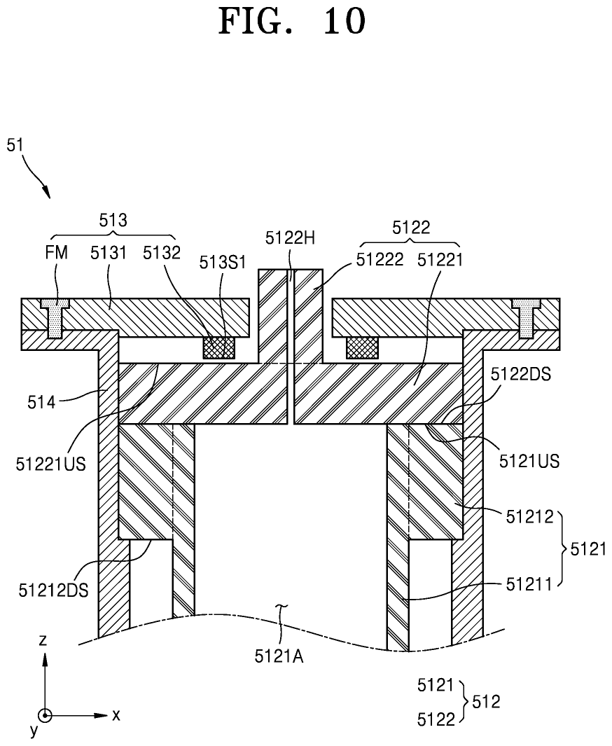

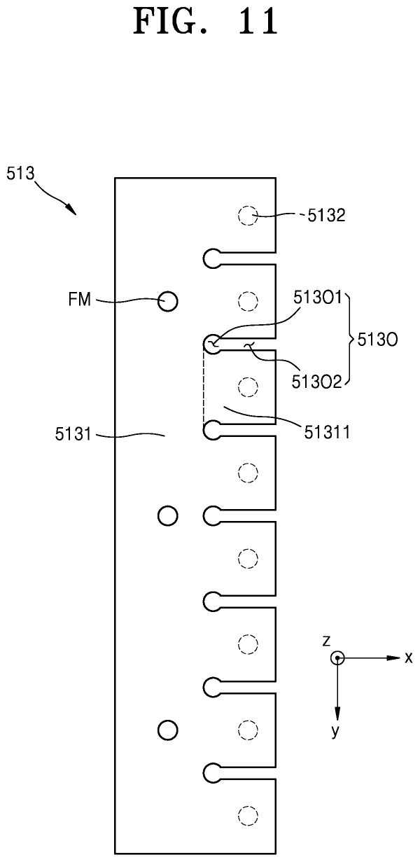

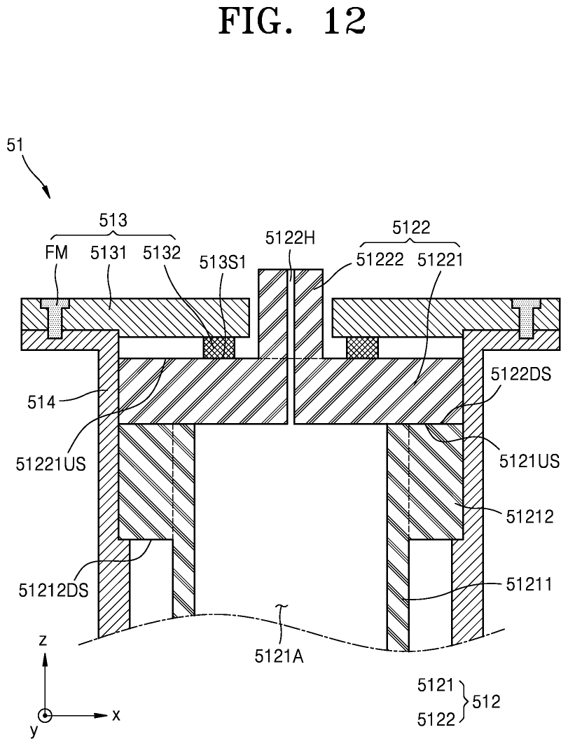

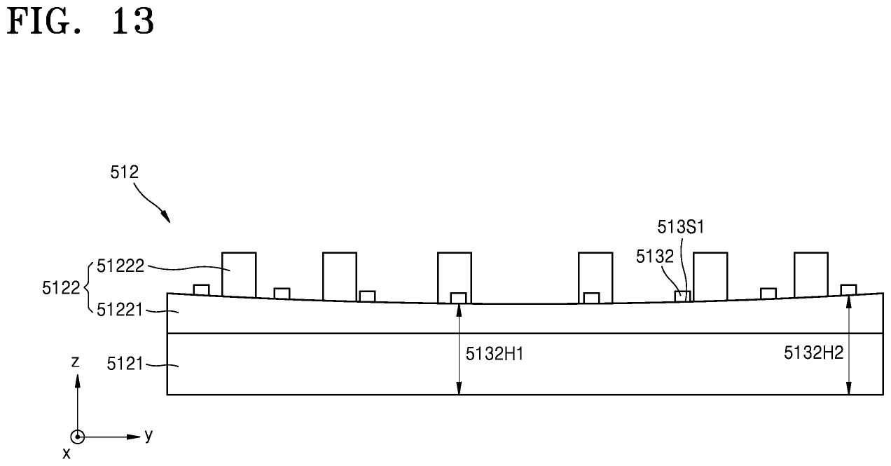

FIG. 10 is a schematic cross-sectional view of a portion of a deposition module 51 in a first state, according to an embodiment. FIG. 11 is a schematic plan view of a close contact portion according to an embodiment. FIG. 12 is a schematic cross-sectional view of a portion of the deposition module 51 in a second state, according to an embodiment. FIG. 13 is a schematic side view of a portion of the deposition module 51 in a second state, according to an embodiment.

For convenience of explanation, FIGS. 10 to 12 illustrate only a spraying portion 512, a close contact portion 513, and a support portion 514 of the deposition module 51, and FIG. 13 illustrates only the spraying portion 512 and a pressing portion 5132.

In FIGS. 10 to 13, the same reference numerals as those in FIGS. 4 and 5 refer to the same members, and redundant descriptions thereof are omitted.

Referring to FIGS. 3 and 10 to 13, the close contact portion 513 may be fixed to the support portion 514, and a pressing surface 513S1 may face one surface of a nozzle portion 5122. The close contact portion 513 may include a close contact frame 5131, a fixing member FM, and the pressing portion 5132.

The close contact frame 5131 may form the exterior of the close contact portion 513. The close contact frame 5131 may be fixed to the support portion 514. The fixing member FM may fix the close contact frame 5131 to the support portion 514.

A plurality of pressing portions 5132 may be provided. The pressing portions 5132 may protrude from the close contact frame 5131 toward one surface of the nozzle portion 5122. Pressing surfaces 513S1 may be respectively disposed on the pressing portions 5132. The pressing surface 513S1 may be disposed on the lower surface of the pressing portion 5132 and may face the upper surface 51221US of the first nozzle portion 51221. The pressing portions 5132 may be spaced apart from each other. That is, the pressing surfaces 513S1 of the pressing portions 5132 may be spaced apart from each other. For example, the pressing portion 5132 may be fixed to the close contact frame 5131 with a separate adhesive. However, this is only an example, and the pressing portion 5132 and the close contact frame 5131 may be integrally formed as a single body.

In the first state, the pressing portion 5132 and the spraying portion 512 may be spaced apart from each other, and in the second state, the pressing portion 5132 may press the spraying portion 512. Accordingly, in the second state, the crucible portion 5121 and the nozzle portion 5122 may come into close contact with each other.

Because the pressing portions 5132 are spaced apart from each other, the contact area between the pressing portions 5132 and the nozzle portion 5122 in the second state may be reduced. Accordingly, in the second state, the amount of heat that the nozzle portion 5122 loses from the close contact portion 513 may be reduced. That is, a phenomenon in which the deposition material M solidifies and clogs the spray hole 5122H may be reduced.

Referring to FIG. 11, separation openings 5130 may be arranged in the close contact frame 5131 so as to separate at least two of the pressing portions 5132 from each other. In a plan view, the separation opening 5130 may be between the two pressing portions 5132. Due to the separation openings 5130, a plurality of teeth 51311 may be disposed on the close contact frame 5131. One pressing portion 5132 may be arranged in one tooth 51311. In such a structure, the flexibility of the close contact frame 5131 may be improved.

The separation openings 5130 may include a first separation opening 51301 and a second separation opening 51302. The first separation opening 51301 may have a longitudinal direction and may be between the two pressing portions 5132. The second separation opening 51302 may be connected to the end portion of the first separation opening 51301 and may have a circular planar shape. In such a structure, the flexibility of the close contact frames 5131 may be improved, and damage to the close contact frames 5131 due to bending may be reduced.

Referring to FIG. 13, in the second state, the degree of thermal expansion of the nozzle portion 5122 may not be uniform. As the nozzle portion 5122 is heated non-uniformly, the degree of thermal expansion of the nozzle portion 5122 in the first direction (e.g., the z-axis direction) may vary in the longitudinal direction of the nozzle portion 5122. For example, the degree of thermal expansion on both sides of the nozzle portion 5122 may be greater than the degree of thermal expansion in the central portion of the nozzle portion 5122. Accordingly, in the second state, the heights of at least two of the pressing portions 5132 may be different from each other. That is, a height 5132H2 of the pressing portion 5132 adjacent to both sides of the nozzle portion 5122 may be higher than a height 5132H1 of the pressing portion 5132 adjacent to the center of the nozzle portion 5122.

In the present embodiment described with reference to FIGS. 10 to 13, because the flexibility of the close contact frame 5131 is secured, the pressing portion 5132 may press the nozzle portion 5122 even when the degree of thermal expansion of the nozzle portion 5122 is not uniform. Therefore, a phenomenon in which the pressing portion 5132 does not properly press the nozzle portion 5122 in the second state, and thus, the deposition material M leaks through the gap between the crucible portion 5121 and the nozzle portion 5122, is avoided.

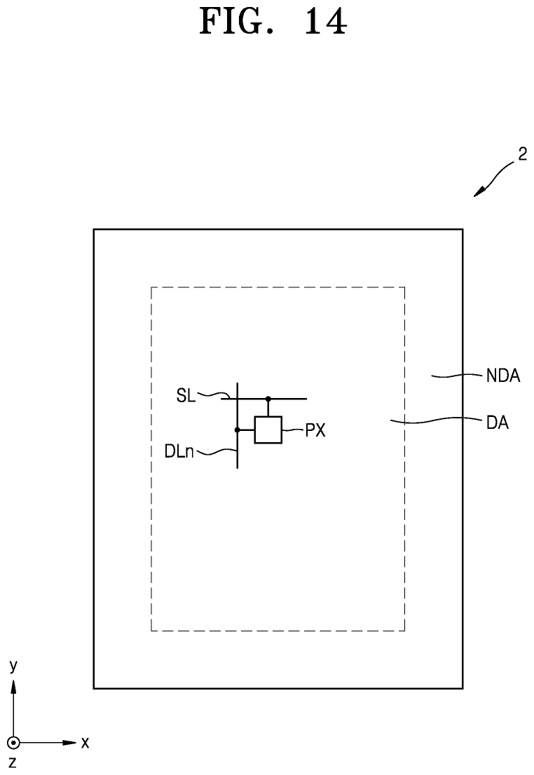

FIG. 14 is a plan view schematically illustrating a display device 2 manufactured by using a display device manufacturing apparatus, according to an embodiment. FIG. 15 is a cross-sectional view schematically illustrating the display device 2 manufactured by using the display device manufacturing apparatus, according to an embodiment.

Referring to FIGS. 14 and 15, the display device 2 may include a display area DA and a non-display area NDA surrounding the display area DA. Pixels PX connected to signal lines, e.g., including a scan line SL and a data line DLn, may be located in the display area DA. The display device 2 may include a display substrate S. The display substrate S may include a substrate 100, an intermediate layer of a display layer DL, and layers excluding a common electrode 23.

The display layer DL and a thin-film encapsulation layer TFE may be disposed on the substrate 100. The display layer DL may include a pixel circuit layer PCL and a display element layer DEL.

The substrate 100 may include glass or polymer resin, such as polyethersulfone, polyarylate, polyetherimide, polyethylene naphthalate, polyethylene terephthalate, polyphenylene sulfide, polyimide, polycarbonate, cellulose triacetate, or cellulose acetate propionate.

A barrier layer (not shown) may be further between the display layer DL and the substrate 100. The barrier layer may prevent filtration of external foreign materials and may be a single layer or layers including an inorganic material, such as silicon nitride (SiNₓ, x>0) or silicon oxide (SiOₓ, x>0).

The pixel circuit layer PCL may be disposed on the substrate 100. The pixel circuit layer PCL may include a thin-film transistor TFT, and a buffer layer 111, a first insulating layer 13a, a second insulating layer 13b, a third insulating layer 15, and a planarization layer 17, which are disposed below and/or above components of the thin-film transistor TFT.

The buffer layer 111 may include an inorganic insulating material, such as silicon nitride, silicon oxynitride, and silicon oxide, and may include a single layer or layers including the inorganic insulating material described above.

The thin-film transistor TFT may include a semiconductor layer 12, and the semiconductor layer 12 may include polysilicon. Alternatively, the semiconductor layer 12 may include amorphous silicon, an oxide semiconductor, or an organic semiconductor. The semiconductor layer 12 may include a channel region 12c, and a drain region 12a and a source region 12b respectively on both sides of the channel region 12c. A gate electrode 14 may overlap the channel region 12c.

The gate electrode 14 may include a low-resistance metal material. The gate electrode 14 may include a conductive material including molybdenum (Mo), aluminum (Al), copper (Cu), titanium (Ti), and the like, and may include a single layer or layers including the conductive material described above.

The first insulating layer 13a between the semiconductor layer 12 and the gate electrode 14 may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂).

The second insulating layer 13b may cover the gate electrode 14. Similar to the first insulating layer 13a, the second insulating layer 13b may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂).

An upper electrode Cst2 of a storage capacitor Cst may be disposed on the second insulating layer 13b. The upper electrode Cst2 may overlap the gate electrode 14 thereunder. At this time, the gate electrode 14 and the upper electrode Cst2, which overlap each other with the second insulating layer 13b therebetween, may form the storage capacitor Cst. That is, the gate electrode 14 may function as a lower electrode Cst1 of the storage capacitor Cst.

As described above, the storage capacitor Cst and the thin-film transistor TFT may overlap each other. In some embodiments, the storage capacitor Cst may not overlap the thin-film transistor TFT.

The upper electrodes Cst2 may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu), and may include a single layer or layers including the material described above.

The third insulating layer 15 may cover the upper electrode Cst2. The third insulating layer 15 may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂). The third insulating layer 15 may include a single layer or layers including the inorganic insulating material described above.

A drain electrode 16a and a source electrode 16b may be disposed on the third insulating layer 15. The drain electrode 16a and the source electrode 16b may each include a material having good conductivity. The drain electrode 16a and the source electrode 16b may each include a conductive material including molybdenum (Mo), aluminum (Al), copper (Cu), titanium (Ti), and the like, and may each include a single layer or layers including the conductive material described above. In an embodiment, the drain electrode 16a and the source electrode 16b may each have a multilayer structure of Ti/Al/Ti.

The planarization layer 17 may include an organic material. The planarization layer 17 may include an organic insulating material, for example, general-purpose polymer such as polymethylmethacrylate (PMMA) or polystyrene (PS), polymer derivatives having a phenolic group, acrylic polymer, imide polymer, aryl ether polymer, amide polymer, fluorine polymer, p-xylene polymer, vinyl alcohol polymer, and any blend thereof.

The display element layer DEL may be disposed on the pixel circuit layer PCL having the above-described structure. The display element layer DEL may include an organic light-emitting diode OLED. A pixel electrode 21 of the organic light-emitting diode OLED may be electrically connected to the thin-film transistor TFT through a contact hole defined in the planarization layer 17.

A pixel PX may include the organic light-emitting diode OLED and the thin-film transistor TFT. The pixel PX may emit red light, green light, or blue light through the organic light-emitting diode OLED, or may emit red light, green light, blue light, or white light through the organic light-emitting diode OLED.

The pixel electrode 21 may include a conductive oxide, such as indium tin oxide (ITO), indium zinc oxide (IZO), zinc oxide (ZnO), indium oxide (In₂O₃), indium gallium oxide (IGO), or aluminum zinc oxide (AZO). In an embodiment, the pixel electrode 21 may include a reflective layer including silver (Ag), magnesium (Mg), aluminum (AI), platinum (Pt), palladium (Pd), gold (Au), nickel (Ni), neodymium (Nd), iridium (Ir), chromium (Cr), or any compound thereof. In an embodiment, the pixel electrode 21 may further include a layer including ITO, IZO, ZnO, or In₂O₃ above and/or below the reflective layer.

A pixel defining layer 19 having an opening 19OP exposing the central portion of the pixel electrode 21 may be disposed on the pixel electrode 21. The pixel defining layer 19 may include an organic insulating material and/or an inorganic insulating material. The opening 19OP may define an emission area for light emitted from the organic light-emitting diode OLED (hereinafter referred to as an emission area EA). For example, the width of the opening 19OP may correspond to the width of the emission area EA.

An emission layer 22 may be arranged in the opening 19OP of the pixel defining layer 19. The emission layer 22 may include a high molecular weight organic material or a low molecular weight organic material, which emits light of a certain color. In an embodiment, the emission layer 22 may include a quantum dot material. This emission layer 22 may be formed by discharging liquid droplets using the display device manufacturing apparatus that is the embodiment.

Although not illustrated, a first functional layer and a second functional layer may be disposed below and above the emission layer 22, respectively. For example, the first functional layer may include a hole transport layer (HTL), or may include an HTL and a hole injection layer (HIL). The second functional layer may be optionally disposed on the emission layer 22. The second functional layer may include an electron transport layer (ETL) and/or an electron injection layer (EIL). The first functional layer and/or the second functional layer may be a common layer completely covering the substrate 100, like the common electrode 23 to be described below.

The common electrode 23 may include a conductive material having a low work function. For example, the common electrode 23 may include a (semi) transparent layer including silver (Ag), magnesium (Mg), aluminum (AI), platinum (Pt), palladium (Pd), gold (Au), nickel (Ni), neodymium (Nd), iridium (Ir), chromium (Cr), lithium (Li), calcium (Ca), or any alloy thereof. Alternatively, the common electrode 23 may further include a layer including ITO, IZO, ZnO, or In₂O₃ on the (semi) transparent layer including the material described above.

The thin-film encapsulation layer TFE may be disposed on the common electrode 23. In an embodiment, the thin-film encapsulation layer TFE may include at least one inorganic encapsulation layer and at least one organic encapsulation layer. As an embodiment, FIG. 15 illustrates that the thin-film encapsulation layer TFE includes a first inorganic encapsulation layer 31, an organic encapsulation layer 32, and a second inorganic encapsulation layer 33, which are sequentially stacked in this stated order.

The first inorganic encapsulation layer 31 and the second inorganic encapsulation layer 33 may each include at least one inorganic material selected from aluminum oxide, titanium oxide, tantalum oxide, hafnium oxide, zinc oxide, silicon oxide, silicon nitride, and silicon oxynitride. The organic encapsulation layer 32 may include a polymer-based material. The polymer-based material may include acrylic resin, epoxy-based resin, polyimide, polyethylene, and the like. In an embodiment, the organic encapsulation layer 32 may include acrylate.

In an embodiment, the thin-film encapsulation layer TFE may have a structure in which the substrate 100 and an upper substrate, which is a transparent member, are bonded to each other by a sealing member so as to seal an internal space between the substrate 100 and the upper substrate. In this case, a moisture absorbent or a filler may be located in the internal space. The sealing member may be a sealant. In an embodiment, the sealing member may include a material that may be cured by a laser. For example, the sealing member may be frit. Specifically, the sealing member may include an organic sealant, such as a urethane-based resin, an epoxy-based resin, and an acrylic resin, or an inorganic sealant, such as silicone. Examples of the urethane-based resin may include urethane acrylate. Examples of the acrylic resin may include butyl acrylate and ethylhexyl acrylate. On the other hand, the sealing member may include a material that may be cured by heat.

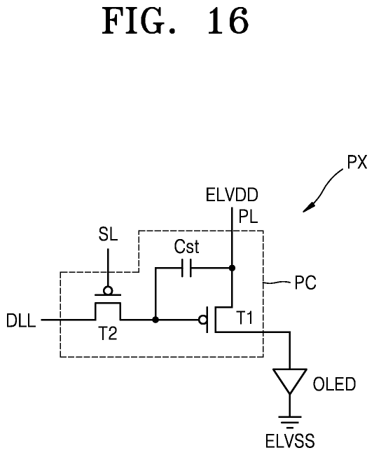

FIG. 16 is an equivalent circuit diagram of a pixel PX of a display panel, according to an embodiment.

The pixel PX may include a pixel circuit PC and a display element connected to the pixel circuit PC. The display element may be an organic light-emitting diode OLED. The pixel circuit PC may include a first thin-film transistor T1, a second thin-film transistor T2, and a storage capacitor Cst. The pixel PX may emit, for example, red light, green light, blue light, or white light from the organic light-emitting diode OLED.

The second thin-film transistor T2, which acts as a switching thin-film transistor, may be connected to a scan line SL and a data line DLL and may be configured to transmit, to the first thin-film transistor T1, a data voltage input from the data line DLL in response to a switching voltage input from the scan line SL. The storage capacitor Cst may be connected to the second thin-film transistor T2 and a driving voltage line PL and may be configured to store a voltage corresponding to a difference between a voltage received from the second thin-film transistor T2 and a first power supply voltage ELVDD supplied to the driving voltage line PL.

The first thin-film transistor T1, which acts as a driving thin-film transistor, may be connected to the driving voltage line PL and the storage capacitor Cst and may be configured to control a driving current flowing from the driving voltage line PL to the organic light-emitting diode OLED according to a voltage value stored in the storage capacitor Cst. The organic light-emitting diode OLED may be configured to emit light having a certain luminance according to the driving current. An opposite electrode (e.g., a cathode) of the organic light-emitting diode OLED may be configured to receive a second power supply voltage ELVSS.

FIG. 16 illustrates that the pixel circuit PC includes two thin-film transistors and one storage capacitor, but the disclosure is not limited thereto. The number of thin-film transistors and the number of storage capacitors may be variously changed according to the design of the pixel circuit PC. For example, the pixel circuit PC may further include four or more thin-film transistors.

According to one or more embodiments, the process of manufacturing the display device may be simplified and the durability of the deposition module may be improved.

The effects of the disclosure are not limited to the above features, and other features that are not mentioned herein will be clearly understood by those of ordinary skill in the art from the claims.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display device manufacturing apparatus comprising:
a mask assembly; and
a deposition source comprising a deposition module configured to supply a deposition material toward the mask assembly,
wherein the deposition module comprises:
a deposition frame having an internal space;
a spraying portion accommodated in the internal space and comprising a crucible portion having a storage space for storing the deposition material, and a nozzle portion connected to the crucible portion and configured to spray the deposition material stored in the storage space;
a heater accommodated in the internal space so as to heat the nozzle portion and configured to be switchable between a first state and a second state, the second state having a heating value higher than a heating value of the first state; and
a close contact portion accommodated in the internal space so as to bring the crucible portion and the nozzle portion into close contact with each other, and
the close contact portion comprises a pressing surface spaced apart from the spraying portion in the first state and configured to press on the spraying portion in the second state.

2. The display device manufacturing apparatus of claim 1, wherein at least one of the crucible portion or the nozzle portion has a thermal expansion coefficient that is higher than a thermal expansion coefficient of the close contact portion.

3. The display device manufacturing apparatus of claim 1, wherein the crucible portion includes a carbon material and the nozzle portion includes a metal material.

4. The display device manufacturing apparatus of claim 1, wherein the close contact portion is detachable from the spraying portion in the first state.

5. The display device manufacturing apparatus of claim 1, wherein the crucible portion comprises:
a first crucible portion configured to store the deposition material and having a longitudinal direction in a first direction toward the nozzle portion; and
a second crucible portion protruding from the first crucible portion in a second direction crossing the first direction,
the nozzle portion comprises:
a first nozzle portion in contact with the crucible portion; and
a second nozzle portion configured to discharge the deposition material and protruding from the first nozzle portion in the first direction, and
the close contact portion is configured to press on the second crucible portion and the first nozzle portion in the second state.

6. The display device manufacturing apparatus of claim 5, wherein a first accommodation groove is disposed in a lower surface of the second crucible portion, and
a first end portion of the close contact portion is accommodated in the first accommodation groove.

7. The display device manufacturing apparatus of claim 5, wherein the close contact portion is further configured to press on an upper surface of the first nozzle portion in the second state.

8. The display device manufacturing apparatus of claim 7, wherein a second accommodation groove is disposed in the upper surface of the first nozzle portion, and
a second end portion of the close contact portion is accommodated in the second accommodation groove.

9. The display device manufacturing apparatus of claim 6, wherein a second accommodation groove is disposed in a side surface of the first nozzle portion, and
a second end portion of the close contact portion is disposed in the second accommodation groove and configured to press on the nozzle portion in the second state.

10. The display device manufacturing apparatus of claim 1, further comprising a support portion configured to support the spraying portion from the deposition frame,
wherein the close contact portion is fixed to the support portion, and
the pressing surface faces one surface of the nozzle portion.

11. The display device manufacturing apparatus of claim 10, wherein the close contact portion comprises:
a close contact frame fixed to the support portion; and
a plurality of pressing portions protruding from the close contact frame toward one surface of the nozzle portion,
the plurality of pressing portions comprise pressing surfaces comprising the pressing surface, and
the pressing surfaces of the plurality of pressing portions are spaced apart from each other.

12. The display device manufacturing apparatus of claim 11, wherein a separation opening configured to separate at least two of the plurality of pressing portions from each other is arranged in the close contact frame.

13. The display device manufacturing apparatus of claim 12, wherein, in the second state, the at least two of the plurality of pressing portions have different heights.

14. The display device manufacturing apparatus of claim 12, wherein the separation opening comprises:
a first separation opening having a longitudinal direction; and
a second separation opening connected to an end portion of the first separation opening and having a circular planar shape.

15. The display device manufacturing apparatus of claim 1, wherein the crucible portion and the close contact portion include a same material.

16. A deposition module comprising:
a deposition frame having an internal space;
a spraying portion accommodated in the internal space and comprising a crucible portion having a storage space for storing a deposition material, and a nozzle portion connected to the crucible portion and configured to spray the deposition material stored in the storage space;
a heater accommodated in the internal space so as to heat the nozzle portion and configured to be switchable between a first state and a second state, the second state having a heating value higher than a heating value of the first state; and
a close contact portion accommodated in the internal space so as to bring the crucible portion and the nozzle portion into close contact with each other, and
wherein the close contact portion comprises a pressing surface spaced apart from the spraying portion in the first state and configured to press on the spraying portion in the second state.

17. The deposition module of claim 16, wherein at least one of the crucible portion or the nozzle portion has a thermal expansion coefficient that is higher than a thermal expansion coefficient of the close contact portion.

18. The deposition module of claim 16, wherein the crucible portion includes a carbon material and the nozzle portion includes a metal material.

19. The deposition module of claim 16, wherein the close contact portion is detachable from the spraying portion in the first state.

20. The deposition module of claim 16, wherein the close contact portion is provided in a form of a clamp.
